(19) United States
(12) Patent Application Publication
(10) Pub. No.: US 2023/0168811 A1
(43) Pub. Date: Jun. 1, 2023

(54) SEMICONDUCTOR STORAGE DEVICE, DATA WRITING METHOD, AND MANUFACTURING METHOD FOR SEMICONDUCTOR STORAGE DEVICE

(71) Applicant: LAPIS Technology Co., Ltd., Yokohama (JP)

(72) Inventor: Toshiharu OKADA, Yokohama (JP)

(73) Assignee: LAPIS Technology Co., Ltd., Yokohama (JP)

(21) Appl. No.: 17/988,034

(22) Filed: Nov. 16, 2022

(30) Foreign Application Priority Data
Nov. 29, 2021 (JP) 2021-192681

(51) Int. Cl. G06F 3/06

(52) U.S. Cl. CPC G06F 3/0616; G06F 3/0653; G06F 3/0647; G06F 3/0679

(57) ABSTRACT

A semiconductor storage device includes: a data writing unit that writes information data to each block of a memory device in accordance with a write command; a verification processing unit that reads the information data out of a destination block every time after the information data is written to that block, and detects the number of error bits in the read-out information data from each block; and a re-writing unit that writes the information data to a block differing from the destination block if the number of error bits exceeds a prescribed threshold.

### CROSS REFERENCE TO RELATED APPLICATION

This application is based upon and claims the benefit of priority of the prior Japanese Patent Application No. 2021-192681, filed on Nov. 29, 2021, the entire contents of which are incorporated herein by reference.

### TECHNICAL FIELD

The present invention relates to a semiconductor storage device, a data writing method for writing data to a semiconductor storage device, and a manufacturing method for a semiconductor storage device.

### BACKGROUND ART

In recent years, with the increase in storage capacity of semiconductor storage devices, NAND flash memory, which has a low unit price per bit, has gained popularity.

With the increase in capacity and integration of NAND flash memory, the problem with stored data being incorrectly read due to changes in written data over time and strenuous read operations has become more pronounced. In other words, an error occurs in the stored data due to a decrease in the charge carrying the stored data and a small amount of charge accumulated in the adjacent memory cells from the read operation.

As a solution to this situation, an error correction code (ECC) is widely used to correct the error and restore correct data.

However, the error correction code has a limit on the number of bits that can be corrected, and if an error with the number of bits exceeding the limit occurs, the original state cannot be restored.

To solve this problem, a semiconductor memory that performs refresh control is proposed in which, when data is read out of the memory, an error detection process is performed on the read-out data, and if the number of error bits exceeds a predetermined threshold, data that has gone through error correction is written back to the memory (refresh process) (See Japanese Patent Application Laid-open Publication No. 2013-125303).

### SUMMARY OF THE INVENTION

### Problems to be Solved by the Invention

Recently, products using NAND flash memory as a read only memory (ROM) have emerged.

For this ROM purpose, a manufacturer ships flash memory with information data (such as programs) written thereto in advance. Then this flash memory is received by a product manufacturer where the flash memory with information data written thereto is mounted on a substrate.

However, because the flash memory is exposed to high temperature in the soldering process for mounting it on a substrate and the like, the charge carrying the stored data sometimes decreases, which can make the data storage period of the flash memory shorter than originally designed.

One possible solution to this problem is to perform the refresh process, i.e., re-writing of data, on flash memory having blocks in which read-out data has a large number of error bits.

However, even in flash memory immediately after data writing, there are sometimes a large number of blocks in which the number of error bits in read-out data exceeds a prescribed threshold. If the refresh control is performed on such flash memory, because of the large number of blocks requiring data to be re-written, the refresh control would take a long time.

In semiconductor storage devices such as flash memory, if written data is not correctly read in the function test before shipping, such a device is deemed defective. Thus, there is a demand for avoiding this situation to improve the yield ratio.

In view of the above-mentioned situations, the present invention aims at providing a semiconductor storage device that can extend the data storage period without increasing the time required for refresh control or decreasing the yield ratio, a data writing method, and a manufacturing method for a semiconductor storage device.

A semiconductor storage device according to the present invention includes: a memory device having a plurality of blocks for storing data; and a memory control unit that controls the memory device, wherein the memory control unit includes: a data writing unit that writes information data to each block of the memory device in accordance with a write command; a verification processing unit that reads the information data out of each destination block every time the information data is written to that destination block, and detects the number of error bits in the read-out information data for each block; and a re-writing unit that writes the information data to a block differing from the destination block if the number of error bits exceeds a prescribed threshold.

Also, a semiconductor storage device according to the present invention includes: a memory device having a plurality of blocks for storing data; and a memory control unit that controls the memory device, wherein the memory control unit includes: a data writing unit that writes information data to each block of the memory device in accordance with a write command; a verification processing unit that reads the information data out of each destination block every time the information data is written to that destination block, and detects the number of error bits in the read-out information data for each block; a re-writing unit that writes the information data to a block differing from the destination block if the number of error bits exceeds a prescribed threshold; and a refresh control unit that reads the information data out of each of the plurality of blocks in accordance with a refresh command, detects the number of error bits in the read-out information data for each of the blocks, and writes data obtained by correcting the read-out information data to a block in which the number of error bits exceeds the threshold.

A data writing method according to the present invention is a data writing method performed in a semiconductor storage device that includes a memory device having a plurality of blocks for storing data and a memory control unit that controls the memory device, the method being performed by the memory control unit and including: writing information data to each block of the memory device in accordance with a write command; reading the information data out of each destination block every time the information data is written to the destination block, and detecting the number of error bits in the read-out information data for each block; and writing the information data to a block differing from the destination block if the number of error bits exceeds a prescribed threshold.

A manufacturing method for a semiconductor memory device according the present invention includes: a semiconductor IC (integrated circuit) manufacturing process in which a semiconductor IC that includes a memory device having a plurality of blocks for storing data and a memory control unit that controls the memory device is manufactured; a data writing process in which information data is written to the memory device of the semiconductor IC; a mounting process in which the semiconductor IC is mounted on a substrate by applying heat; and a refresh process in which a refresh operation is performed on the memory device of the semiconductor IC, wherein the data writing process includes: writing information data to each of block of the memory device in accordance with a write command; reading the information data out of each destination block every time the information data is written to that destination block, and detecting the number of error bits in the read-out information data for each block; and writing the information data to a block differing from the destination block if the number of error bits exceeds a prescribed threshold, and wherein, in the refresh process, the memory control unit reads the information data out of each of the plurality of blocks, detects the number of error bits in the read-out information data for each of the blocks, and writes data obtained by correcting the read-out information data to a block in which the number of error bits exceeds the threshold.

A semiconductor storage device according to the present invention undergoes, at a manufacturer of the semiconductor storage device, a process of writing information data to each block of the memory, reading the information data out of each destination block every time the information data is written to that destination block, and detecting the number of error bits in the read-out information data for each of the blocks. In this process, if the number of error bits does not exceed a prescribed threshold, it is determined that data has been successfully written to the destination block. On the other hand, if the number of error bits exceeds the prescribed threshold, it is determined that data writing to the destination block has failed, and the information data is written to a block differing from the destination block.

This way, it is possible to achieve a semiconductor storage device in a state where, upon data reading, the number of error bits in the read-out data for each block is kept below a prescribed threshold, or in other words, the number of error bits is well below the upper limit of the number of error bits that can be corrected.

Thus, according to this semiconductor storage device, even if the semiconductor storage device is exposed to high heat in the mounting process, the number of error bits in read-out data does not reach the upper limit of the number of error bits that can be corrected, which makes it possible to extend the data storage period and improve the yield ratio.

Also, in a case where the refresh control is performed on the semiconductor storage device in order to further extend the data storage period, the frequency of the refresh process (data re-writing) can be reduced, which makes it possible to shorten the time required for the refresh control.

### BRIEF DESCRIPTION OF THE DRAWINGS

FIG. 1 is a block diagram illustrating a configuration example of a memory device 200 of Embodiment 1 of the semiconductor storage device according to the present invention.

FIG. 2 is a flowchart illustrating steps of data writing control in Embodiment 1.

FIG. 3 is a flowchart illustrating an example of the refresh control steps.

FIG. 4 is a block diagram illustrating the configuration of a memory device 200A of Embodiment 2.

FIG. 5 is a flowchart illustrating steps of data writing control in Embodiment 2.

FIG. 6 is a flowchart illustrating steps of margin block back-up control.

FIG. 7 is a flowchart illustrating another example of the refresh control steps.

FIG. 8 is a manufacturing process diagram illustrating each process that takes place between production of a semiconductor IC including the memory device 200 or 200A and implementation of the pre-refresh control.

### DETAILED DESCRIPTION OF EMBODIMENTS

Below, embodiments of the present invention will be explained in detail with reference to figures.

### Embodiment 1

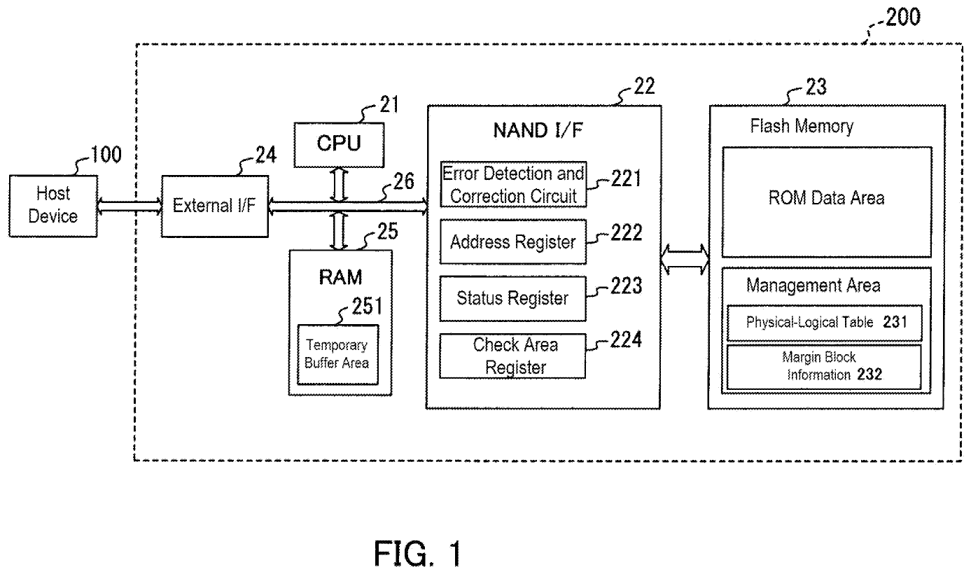

FIG. 1 is a block diagram illustrating a configuration example of a memory device 200 of Embodiment 1 of the semiconductor storage device according to the present invention.

The memory device 200 writes information data representing program data and the like to a non-volatile memory such as NAND flash memory installed therein according to a write command from an externally connected host device 100.

The memory device 200 also reads the information data written in the above-described memory device in accordance with a read command from the host device 100, performs error correction on the read-out data, and outputs the corrected data to the host device 100. Furthermore, the memory device 200 detects the number of error bits in the information data read out of the semiconductor memory device in accordance with a refresh command from the host device 100, and performs a refresh process to re-write the information data if the number is greater than a predetermined threshold.

As illustrated in FIG. 1, the memory device 200 includes: a CPU (central processing unit) 21, a NAND interface unit 22, NAND flash memory 23, an external interface unit 24, a RAM (random access memory) 25, and a CPU bus 26.

The CPU 21 runs respective programs for refresh control, data writing control, and data reading control, which are stored in advance in a ROM (not shown) built therein. By running those programs, the CPU 21 controls the NAND interface unit 22, the external interface unit 24 and the RAM 25 through the CPU bus 26.

Upon receiving a write command, data for writing, and a destination address for writing through the CPU bus 26, the NAND interface unit 22 performs a data erasure process on a block that has the destination address, and writes the data for writing to the address of the destination block in the flash memory 23. Upon receiving a read command and a destination address for the data reading through the CPU bus 26, the NAND interface unit 22 reads the data stored in the destination address out of the flash memory 23, and sends this data to the CPU bus 26.

The NAND interface unit 22 includes an error detection and correction circuit 221, an address register 222 a status register 223, and a check area register 224.

The error detection and correction circuit 221 generates write data by treating the data for writing, which is sent to the CPU bus 26, with an error-correction code.

Also, the error detection and correction circuit 221 performs error detection on the read-out data from the flash memory 23, counts the number of error bits as a result of the error detection, and registers error bit number information that represents the number of error bits in the status register 223. The error bit number information stored in the status register 223 is read out to the CPU bus 26 in accordance with a command from the CPU 21.

The address register 222 stores therein data addresses that have been specified for reading or writing.

The check area register 224 stores therein check area designating information that represents check areas subjected to error detection within the data storage area of the flash memory 23.

Furthermore, the NAND interface unit 22 has the function of reading data out of the data storage of the flash memory 23 specified by the check area designating information stored in the check area register 224, and detecting the number of error bits in the read-out data. In this process, the error bit number information that indicates the number of detected error bits is stored in the status register 223, and read out to the CPU bus 26 in accordance with a command from the CPU 21.

The flash memory 23 includes, as the data storage areas, a ROM data area in which information data such as programs are stored, and a management information area in which various types of management information is stored, for example. The management information includes a logical-physical table 231 that is a conversion table between a logical address and a physical address, and margin block information 232. The logical-physical table 231 is a table that associates externally specified addresses (logical addresses) with logical addresses that each indicate a physical location in the data storage area of the flash memory 23. The margin block information 232 indicates the block number of unused blocks that belong to a margin area in the ROM data area.

The external interface unit 24 is connected to the host device 100 to receive various types of commands, addresses and data from the host device 100 and send them to the CPU bus 26. Also, when read-out data from the flash memory 23 is sent to the CPU bus 26 via the NAND interface unit 22, the external interface unit 24 sends this read-out data to the host device 100.

The RAM 25 includes a temporary buffer area 251 that temporarily stores variables, stack information, write data and read data that are used when the programs are running.

When data is to be written to the memory device 200, the host device 100 sends a write command and data for writing to the external interface unit 24. Then the external interface unit 24 stores the data for writing in the temporary buffer area 251 of the RAM 25, and notifies the CPU 21 of the received write command via the CPU bus 26. The CPU 21 starts the write control in accordance with the write command, and provides the NAND interface unit 22 with the temporary buffer area 251 in which the destination address for writing and the data for writing are stored. This way, the data for writing, which is stored in the temporary buffer area 251, is read out to the CPU bus 26, and is written to the destination address of the flash memory 23 by the NAND interface unit 22 as write data. After the writing process is completed, the CPU 21 notifies the host device 100 of the completion of writing via the external interface unit 24.

On the other hand, when data is to be read out of the memory device 200, the host device 100 sends a read command to the external interface unit 24. Upon receiving the read command, the external interface unit 24 notifies the CPU 21 of the received read command via the CPU bus 26. The CPU 21 starts the read control in accordance with the read command, and provides the NAND interface unit 22 with the temporary buffer area 251 in which the destination address for reading and the read data are stored. Then the NAND interface unit 22 reads the data stored in the destination address out of the flash memory 23, and after performing error correction on the read-out data, stores the read-out data in the temporary buffer area 251 of the RAM 25. After this reading process is completed, the CPU 21 reads the read-out data stored in the temporary buffer area 251, and sends this data to the host device 100 via the external interface unit 24.

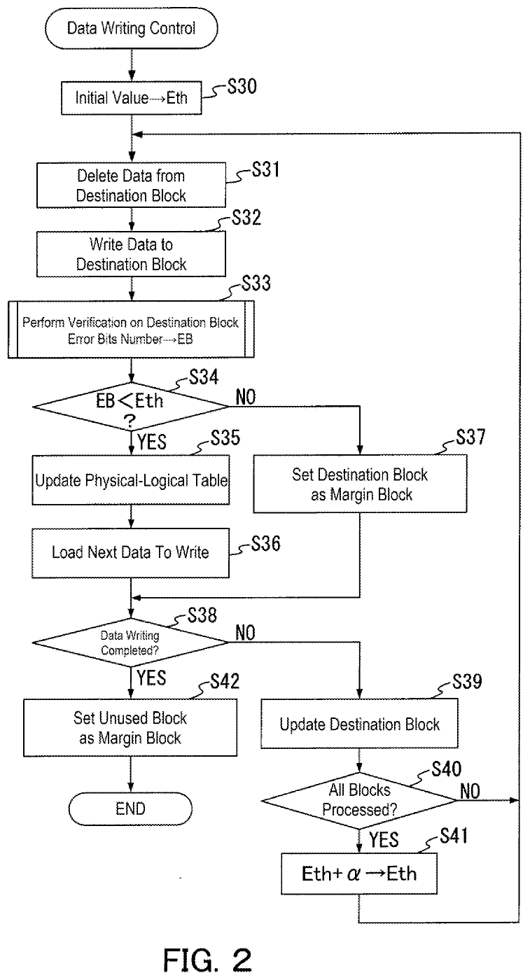

FIG. 2 is a flowchart illustrating steps of data writing control performed by the CPU 21 upon receiving a write command, data for writing, and a destination address for writing from the host device 100.

First, the CPU 21 sets a standard error bit number expected in data reading that is performed immediately after data writing, as an initial value for a threshold Eth for the number of error bits (Step S30).

Next, the CPU 21 controls the NAND interface unit 22 to erase all of the data from a block that includes a page of the destination address described above in the flash memory 23 (Step S31). In Step S31, the NAND interface unit 22 performs a data erasure process on the block that includes the page of the destination address for writing in the flash memory 23 to erase all the data.

Next, the CPU 21 controls the NAND interface unit 22 to write the data for writing to the block including the destination address for writing (Step S32). In Step S32, the NAND interface unit 22 writes the write data, which is obtained by correcting the data for writing with an error-correction code, to the destination block.

Next, the CPU 21 controls the NAND interface unit 22 to perform a verification process described below on the destination block to which the data has been written (Step S33). In Step S33, the NAND interface unit 22 starts the verification process by reading the write data written in the destination block out of the flash memory 23. Next, the NAND interface unit 22 detects the number of error bits in this read-out data by performing error detection on the data that has been read (read data). Then, the NAND interface unit 22 stores error bit number information EB indicating the number of error bits in the status register 223.

Next, the CPU 21 reads this error bit number information EB stored in the status register 223, and determines whether the error bit number information EB is smaller the threshold Eth or not (Step S34).

In Step S34, if the error bit number information EB is smaller the threshold Eth, the CPU 21 determines that the data has been successfully written to the destination block. Then the CPU 21 controls the NAND interface unit 22 to update a part of the logical-physical table 231 that corresponds to this destination block (Step S35). In Step S35, the NAND interface unit 22 updates the logical-physical table 231 with the content indicating the correspondence relationship between the logical address and the physical address in the destination block to which data has been successfully written as described above.

Next, the CPU 21 loads the next data for writing, which was sent from the host device 100, and stores this data in the temporary buffer area 251 (Step S36).

In Step S34, if the error bit number information EB is equal to or greater than the threshold Eth, the CPU 21 determines that the data writing to that block has failed, and updates the margin block information 232 to set this block to a margin block (Step S37). That is, in Step S37, in order to set the block with failed data writing to a margin block, the CPU 21 controls the NAND interface unit 22 such that the block number of the block with failed data writing is added to the margin block information 232 stored in the management area of the flash memory 23.

After Step S36 or S37 is performed, the CPU 21 determines whether all the data has been written or not (Step S38), and if data writing is not finished, the CPU 21 updates the destination block to a next block (Step S39). For example, in the ROM data area, the CPU 21 increments the block number of the block to which data was written in the immediately preceding cycle by one, and sets a block having that block number as the destination block for next data writing. If the block number of the block to which data was written in the immediately preceding cycle was the last block number in the ROM data area (excluding the margin area), or in other words, if a plurality of unused blocks in the ROM data area have already been used as the destination block, the CPU 21 sets the first margin block in the margin area as the destination block for next data writing.

Next, the CPU 21 determines whether all the blocks in the ROM data area have been used as the destination block for data writing or not (Step S40). In Step S40, if it is determined that all of the blocks have not been used as the destination block for data writing, the CPU 21 returns to Step S31 described above, and repeatedly performs the operation described above until all the data has been written.

On the other hand, if it is determined that all of the blocks have been used as the destination block in Step S40, or in other words, the first margin block was set as the destination block in Step S39, the CPU 21 adds a prescribed value a to the threshold Eth to obtain a new threshold Eth (Step S41). After Step S41, the CPU 21 returns to Step S31, and repeatedly performs the operation described above including re-writing of data (S31 and S32), determining whether data writing was successful or not (S34), conducting the verification process (S33) and the like.

That is, the margin blocks belonging to the margin area after all the blocks have been used for the destination block are the blocks in which data writing were deemed unsuccessful based on the threshold Eth before Step S41. Thus, in the present invention, the value of the threshold Eth is increased (+α) in Step S41 so that a greater number of blocks will be deemed successful in the second data writing.

If it is determined that all the data has been written in Step S38 through the series of processes from Step S30 to S41 described above, the CPU 21 updates the margin block information 232 so that all unused blocks not used for data writing are registered as margin blocks (Step S42). That is, in Step S42, the CPU 21 controls the NAND interface unit 22 such that the block numbers of all the unused blocks not used for data writing are added to the margin block information 232 stored in the management area of the flash memory 23.

Upon completing Step S42, the CPU 21 ends the data writing control process.

Below, the refresh control performed on the memory device 200 with information data written thereto will be explained.

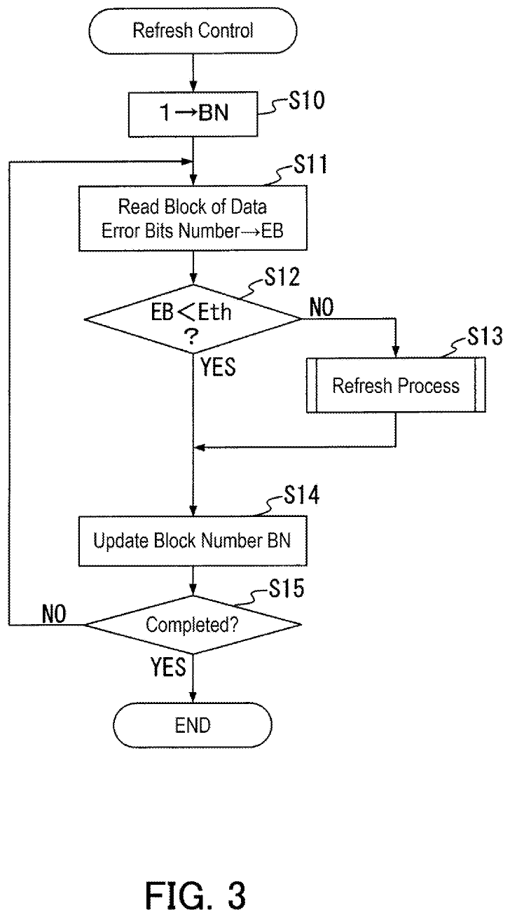

FIG. 3 is a flowchart illustrating steps of the refresh control performed by the CPU 21 in response to a refresh request sent from the host device 100.

First, the CPU 21 sets the initial value of the block number BN to “1” (Step S10).

Next, the CPU 21 controls the NAND interface unit 22 to read the written data out of the block specified by the block number BN in the ROM data area of the flash memory 23 (Step S11). In Step S11, the NAND interface unit 22 reads the data written to this block out of the flash memory 23. Then the NAND interface unit 22 performs an error detection process on the read-out data, and stores error bit number information EB indicating the number of error bits in the status register 223 as the error detection result.

Next, the CPU 21 determines whether the error bit number information EB stored in the status register 223 is smaller than the prescribed threshold Eth or not (Step S12).

In Step S12, if the error bit number information EB is equal to or greater than the threshold Eth, the CPU 21 controls the NAND interface unit 22 to perform the refresh control (Step S13). In Step S13, the NAND interface unit 22 performs the refresh control described below on the flash memory 23. That is, the NAND interface unit 22 reads and deletes data written to the block indicated by the block number BN, and writes data obtained by performing error correction on this read-out data to the block indicated by the block number BN.

After Step S13 is performed, or if it is determined that the error bit number information EB is smaller than the threshold Eth in Step S12, the CPU 21 updates the block number BN by incrementing the value by one, for example (Step S14).

Next, the CPU 21 determines whether the series of processes from Step S11 to Step S14 described above has conducted on all of the blocks belonging to the ROM data area of the flash memory 23 or not (Step S15). The CPU 21 repeatedly performs the series of processes from Step S11 to S14 until it is determined that the process has been completed in Step S15.

By performing this refresh control on the memory device 200 that is mounted on a substrate, even if the number of error bits is increased to the upper limit of the error bits that can be corrected due to the high heat applied during the substrate mounting process, for example, it is possible to lower this number below a prescribed value. As a result, the data storage period is made longer.

In this refresh control, the greater the number of blocks that have the error bit number exceeding the threshold value Eth, the more frequently the refresh process (S13) of FIG. 3 needs to be performed, and as a result, the longer it takes for the refresh control.

Furthermore, if there is a page where the number of error bits exceeds the upper limit of error bits that can be corrected, then it would not be possible to restore data, and because that product (memory device 200) is deemed defective, the yield ratio would worsen.

In view of those problems, the memory device 200 is equipped with a memory control unit (CPU 21, NAND interface unit 22) having the data writing unit, the verification processing unit, and the re-writing processing unit described below, for controlling the non-volatile memory device (23) having a plurality of blocks for storing data.

The data writing unit (S31, S32) writes information data to each of the blocks of the memory device in accordance with a write command. The verification processing unit (S33) reads the information data from a destination block after the information data has been written into the destination block, and detects the number of error bits (EB) in the read-out information data for each block. The re-writing processing unit ((S34 to S41), S31, S32) determines that data has been successfully written to the destination block if the number of error bits does not exceed a prescribed threshold (Eth). On the other hand, if the number of error bits exceeds the prescribed threshold value, the re-writing processing unit determines that data writing to the destination block has failed, and writes the information data to a block differing from the destination block (S37, S39, S31, and S32).

Here, the memory device 200 performs the verification while writing data (S31, S32), and detects the number of error bits in the data read out in this verification (S33). Then the memory device 200 re-writes data (S31, S32) while gradually increasing the threshold (S41) until the counted number of error bits goes below the threshold (Eth).

This way, it is possible to realize the memory device 200 in which, upon data writing, the number of error bits in the data read out of each block is smaller than a prescribed threshold, or in other words, the number of error bits is well below the upper limit of the number of error bits that can be corrected.

As a result, with the memory device 200, it is possible to improve the data storage period and yield ratio.

Also, in performing the refresh control described with reference to FIG. 3 on the memory device 200, the frequency of actually performing the refresh process (S13) is reduced, which makes it possible to shorten the time required for the refresh control.

### Embodiment 2

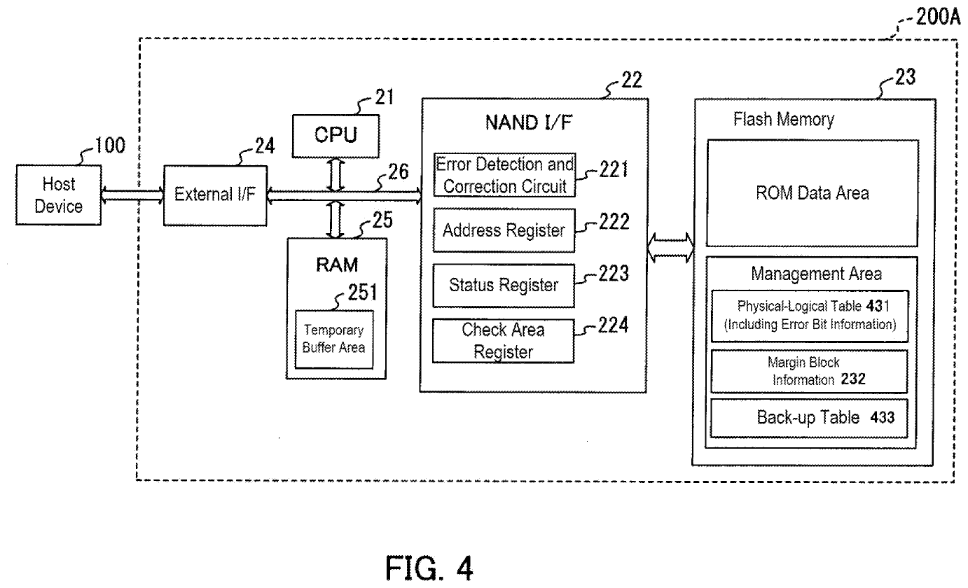

FIG. 4 is a block diagram illustrating a configuration example of a memory device 200A of Embodiment 2 of the semiconductor storage device according to the present invention.

The memory device 200A of FIG. 4 has the same configuration as that illustrated in FIG. 1 except that a logical-physical table 431 is used instead of the logical-physical table 231 illustrated in FIG. 1, and a back-up table 433 is newly added.

The logical-physical table 431 includes error bit information indicating the number of error bits after data writing in association with each logical address of each block. The back-up table 433 is stored in the management area of the flash memory 23 in a manner similar to the logical-physical table 431, and indicates the correspondence relationship between logical addresses of back-up data written to margin blocks and physical addresses of those margin blocks.

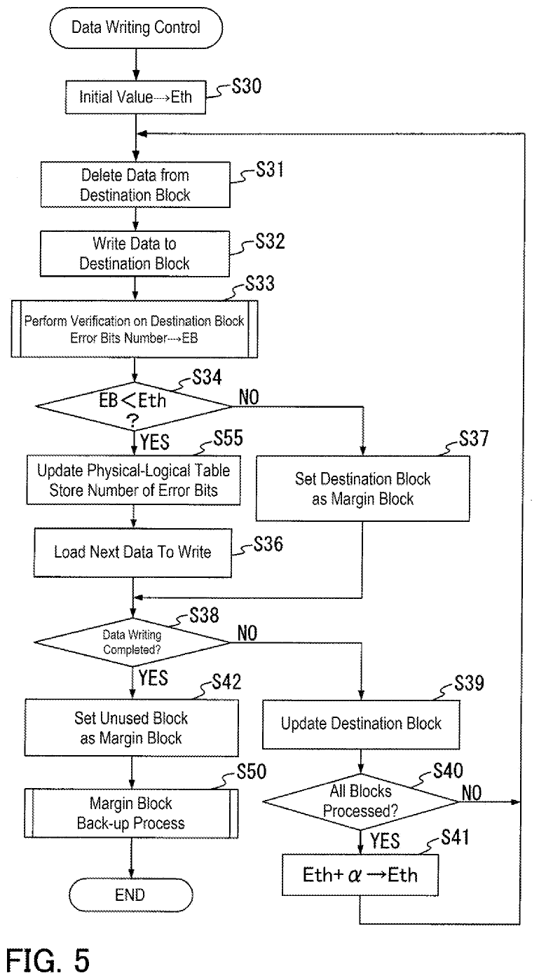

FIG. 5 is a flowchart representing steps of data writing control performed by the CPU 21 of the memory device 200A illustrated in FIG. 4.

The flowchart of FIG. 5 has the same steps and sequences as those of the flowchart of FIG. 2 except that Step S35 is replaced with Step S55, and Step S50 is newly added immediately after Step S42.

Thus, the operation of Steps S55 and S50 will be mainly explained below.

That is, in the flowchart illustrated in FIG. 5, if it is determined that the error bit number information EB is smaller than the threshold Eth in Step S34, the CPU 21 determines that the data has been successfully written to the destination block (block to which data was written in Step S32). Then the CPU 21 controls the NAND interface unit 22 to update a part of the logical-physical table 431 that corresponds to this destination block, and add the error bit number information EB acquired in Step S33 to the logical-physical table 431 in association with the logical address of the corresponding destination block (Step S55).

In the flowchart of FIG. 5, the CPU 21 performs the margin block back-up process (Step S50) after Step S42.

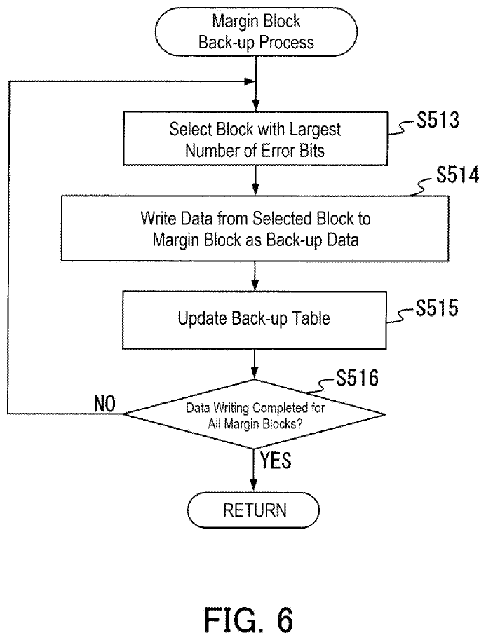

FIG. 6 is a flowchart illustrating steps of the margin block back-up process performed by the CPU 21 in detail.

In FIG. 6, first, the CPU 21 controls the NAND interface unit 22 to select a block with a greatest number of error bits, among a plurality of blocks stored in the logical-physical table 431 stored in the management area of the flash memory 23 (Step S513). In Step S513, the NAND interface unit 22 selects one block at a time from the plurality of blocks stored in the logical-physical table 431 in a descending order from a largest error bit number.

Next, the CPU 21 controls the NAND interface unit 22 to write the data written in the selected one block to a margin block (Step S514). In Step S514, the NAND interface unit 22 reads the data out of the selected one block, and writes back-up data, which is obtained by correcting this read-out data, to a margin block.

Next, the CPU 21 controls the NAND interface unit 22 to update the back-up table 433 based on the logical address of the back-up data written to the margin block and the physical address of the margin block (Step S515).

Next, the CPU 21 determines whether the back-up data has been written to all of the margin blocks or not (Step S516). In Step 5516, if it is determined that the back-up data writing has not been completed, the CPU 21 returns to Step S513, and again performs the operation described above. That is, until the back-up data is written to all of the margin blocks indicated by the margin block information 232, the CPU 21 repeatedly performs the series of controls from Steps S513 to S516.

In Step S516, if it is determined that the back-up data has been written to all of the margin blocks, the CPU 21 exits the margin block back-up process described in FIG. 6, and returns to the data writing control described in FIG. 5.

Below, the refresh control performed on the memory device 200A to which information data is written will be explained.

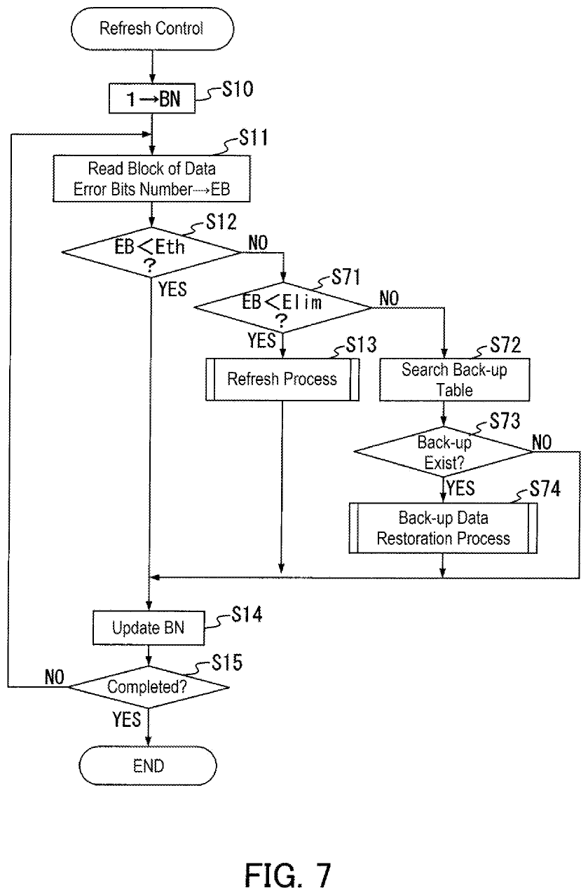

FIG. 7 is a flowchart illustrating steps of the refresh control performed by the CPU 21 of the memory device 200A in response to a refresh request sent from the host device 100.

First, the CPU 21 sets the initial value of the block number BN to “1” (Step S10).

Next, the CPU 21 controls the NAND interface unit 22 to read the written data out of the block specified by the block number BN in the ROM data area of the flash memory 23 (Step S11). In Step S11, the NAND interface unit 22 reads the data written to this block out of the flash memory 23. Then the NAND interface unit 22 performs an error detection process on the read-out data, and stores error bit number information EB indicating the number of error bits in the status register 223 as the error detection result.

Next, the CPU 21 determines whether the error bit number information EB stored in the status register 223 is smaller than the prescribed threshold Eth or not (Step S12).

In Step S12, if it is determined that the error bit number information EB is equal to or greater than the threshold Eth, the CPU 21 determines whether the error bit number information EB is smaller than a threshold Elim or not (Step S71). The threshold Elim represents the upper limit of the number of error bits that can be corrected by the error detection and correction circuit 221 illustrated in FIG. 4, and is greater than the threshold Eth. That is, in Step S71, after the error detection is performed on the data read out of the flash memory 23, whether the number of error bits (EB) exceeds the number of error bits that can be corrected by the error detection and correction circuit 221 or not is determined.

In Step S71, if the error bit number information EB is smaller than the threshold Elim, the CPU 21 controls the NAND interface unit 22 to perform the refresh control (Step S13). In Step S13, the NAND interface unit 22 performs the refresh control described below on the flash memory 23. That is, the NAND interface unit 22 reads and deletes data written to the block indicated by the block number BN, and writes data obtained by performing error correction on this read-out data to the block indicated by the block number BN.

In Step S71, if it is determined that the error bit number information EB is equal to or greater than the threshold Elim, the CPU 21 searches the back-up table 433 (Step S72) to determine whether there is back-up data corresponding to the address of the block indicated by the block number BN or not (Step S73).

In Step S71, if the error bit number information EB is smaller than the threshold Elim, the CPU 21 controls the NAND interface unit 22 to perform the data restoration process described below (Step S13). In Step S74, the NAND interface unit 22 first deletes data written in the block indicated by the block number BN. Then the NAND interface unit 22 writes the back-up data corresponding to the block indicated by the block number BN to the block for data restoration using the back-up data.

After Step S13 or S74, or if it is determined that the error bit number information EB is smaller than the threshold Eth in Step S12, or if it is determined that there is no back-up data in Step S73, the CPU 21 updates the block number BN by incrementing the value by one, for example (Step S14).

Next, the CPU 21 determines whether the series of processes from Step S11 to Step S14 described above has been performed on all of the blocks belonging to the ROM data area of the flash memory 23 or not (Step S15). The CPU 21 repeatedly performs the series of processes from Steps S11 to S14 or Steps S71 to S74 until it is determined that the process has been completed in Step S15.

As described above, in a manner similar to the memory device 200, the memory device 200A identifies a block where the number of error bits (EB) found in the read-out data in the verification (S33), which is performed upon data writing, is equal to or greater than the prescribed threshold Eth, and makes that block a margin block (S37). However, in the memory device 200A, the back-up process described below is performed using this margin block (S50). That is, the memory device 200A selects one block at a time where the number of error bits (EB) found in the read-out data from the verification is smaller than the threshold Eth in a descending order from a largest error bit number, and writes the data written in the selected block to the margin block (S514).

Furthermore, in the memory device 200A, the refresh control illustrated in FIG. 7 is performed in response to a refresh request from the host device 100.

With this refresh control, even if the number of error bits found in the read-out data read out of the flash memory 23 exceeds the upper limit (Elim) of the number of error bits that can be corrected, the memory device 200A is able to restore (S74) the data using the back-up data written to the margin block.

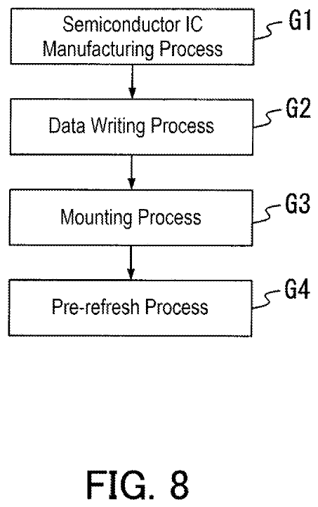

FIG. 8 is a manufacturing process diagram illustrating each process that takes place between production of a semiconductor IC including the memory device 200 or 200A described above and implementation of the pre-refresh control.

As illustrated in FIG. 8, first, a semiconductor IC including the memory device 200 or 200A is manufactured (semiconductor IC manufacturing process G1).

Next, according to the data writing control steps described above with reference to FIG. 2 or FIG. 5, information data is written to the flash memory 23 of the memory device 200 or 200A included in the manufactured semiconductor IC (data writing process G2).

Here, the manufacturer of the semiconductor IC ships the semiconductor IC including the memory device 200 or 200A that has the information data written thereto as described above.

According to this semiconductor IC, even if the semiconductor IC is exposed to high heat in the mounting process, the number of error bits in read-out data does not reach the upper limit of the number of error bits that can be corrected, which makes it possible to extend the data storage period and improve the yield ratio. Furthermore, according to this semiconductor IC, in performing the refresh control, the frequency of actually performing the refresh process on each block is reduced, which makes it possible to shorten the time required for the refresh control.

After arriving at a product manufacturer, the semiconductor IC is mounted on a substrate through heat treatment where an electrode pad of the semiconductor IC and an electrode pad on the surface of the substrate are soldered to each other (mounting process G3).

Then, according to the refresh control steps described above with reference to FIG. 3 or FIG. 7, the refresh process is performed on the data stored in the flash memory 23 of the semiconductor IC mounted on this substrate (pre-refresh process G4).

With this pre-refresh process G4, the data storage period and the yield ratio can further be improved.

In the memory device 200A of Embodiment 2, the back-up blocks were selected in a descending order from a largest error bit number as described above, but the order of selection is not limited thereto, and the back-up blocks may also be selected based on another condition not related to the number of error bits. For example, in the data writing process illustrated in FIG. 5, the verification process (S33) is repeatedly performed while changing the threshold Eth (S41), but instead, it is possible to repeatedly perform the verification process while changing the voltage value of the reference voltage used for data determination upon reading, and select a block that was most frequently read out as a back-up block.

Also, in the memory device 200A, any one of the SLC (single level cell), MLC (multiple level cell), and TLC (triple level cell) may be used for the recording method of the NAND flash memory 23.

The flash memory 23 may also be configured such that the recording method for writing information data to the ROM data area and the recording method for writing back-up data differ from each other.

For example, in order to improve the storage performance of the back-up data, a configuration may be adopted where the MCL method or the TLC method is used for the recording method for writing information data, and the SLC method, which has higher data storage quality, is used for the recording method for writing back-up data.

Furthermore, in the memory device 200A, the data restoration process (S74) is performed by using the back-up data written to the margin data in the refresh control, but instead, the data restoration process (S74) may be performed when the number of error bits in data read out during a normal reading operation exceeds the threshold Elim.

In the respective embodiments described above, NAND flash memory is used for the flash memory 23, but instead, another type of non-volatile memory such as NOR flash memory may be used.

What is claimed is:

1. A semiconductor storage device, comprising:
a memory device having a plurality of blocks for storing data; and
a memory control unit that controls the memory device,
wherein the memory control unit includes:
a data writing unit that writes information data to each of the plurality of blocks of the memory device in accordance with a write command;
a verification processing unit that reads the information data out of each of destination blocks of the plurality of blocks every time the information data is written to the destination block, and detects a number of error bits in the read-out information data for each destination block; and
a re-writing processing unit that writes the information data to a block differing from the destination block, if the number of error bits exceeds a prescribed threshold.

2. The semiconductor storage device according to claim 1,
wherein the memory control unit includes a back-up writing processing unit that writes the information data as back-up data to an unused block or a block in which the number of error bits exceeds the prescribed threshold, among the plurality of blocks.

3. The semiconductor storage device according to claim 2,
wherein the back-up writing processing unit selects blocks from the plurality of blocks having information data written thereto by the data writing unit, or from blocks written to by the re-writing processing unit, in a descending order from a block having a largest number of detected error bits, and uses the data written to the selected blocks as the back-up data.

4. The semiconductor storage device according to claim 2,
wherein the memory device is a NAND flash memory, and
wherein the memory control unit writes the information data using one method selected from a single level cell method, a triple level method, and a multiple level method, and writes the back-up data using another method selected from the single level cell method, the triple level method, and the multiple level method.

5. The semiconductor storage device according to claim 2,
wherein the memory control unit includes an error detection and correction circuit that performs error detection and correction on the information data read out of the destination block, and
wherein, when the number of error bits exceeds an upper limit of a number of error bits that can be corrected by the error detection and correction circuit, the memory control unit restores data by writing the back-up data to a block where the number of error bits exceeds the upper limit.

6. The semiconductor storage device according to claim 1,
wherein the re-writing processing unit includes:
a margin block setting unit that sets the destination block as a margin block when the number of error bits exceeds the prescribed threshold;
a threshold incrementing unit that sets a new threshold by incrementing the prescribed threshold by a prescribed value after the information data has been written to all of the plurality of blocks; and
a re-writing unit that re-writes the information data to the margin block as a new block to which the information data is written, after the information data has been written to all of the plurality of blocks,
wherein, when a number of error bits detected by the verification processing unit in information data read out of said new block is equal to or greater than the new threshold, the re-writing processing unit writes the information data to a block differing from said new block.

7. A semiconductor storage device, comprising:
a memory device having a plurality of blocks for storing data; and
a memory control unit that controls the memory device,
wherein the memory control unit includes:
a data writing unit that writes information data to each of the plurality of blocks of the memory device in accordance with a write command;
a verification processing unit that reads the information data out of each of destination blocks of the plurality of blocks every time the information data is written to the destination block, and detects a number of error bits in the read-out information data for each destination block;
a re-writing processing unit that writes the information data to a block differing from the destination block if the number of error bits exceeds a prescribed threshold; and
a refresh control unit that reads the information data out of each of the plurality of blocks in accordance with a refresh command, detects the number of error bits in the read-out information data for each block, and writes data obtained by correcting the read-out information data to a block in which the number of error bits exceeds the prescribed threshold.

8. The semiconductor storage device according to claim 7,
wherein the memory control unit includes a back-up writing unit that writes the information data as back-up data to an unused block or a block in which the number of error bits exceeds the prescribed threshold, among the plurality of blocks, and
wherein, when the number of error bits exceeds an upper limit of a number of error bits that can be corrected, the refresh control unit restores data by writing the back-up data to a block where the number of error bits exceeds the upper limit.

9. A data writing method performed in a semiconductor storage device having a memory device including a plurality of blocks for storing data and a memory control unit that controls the memory device, the method being performed by the memory control unit and comprising:
writing information data to each of the plurality of blocks of the memory device in accordance with a write command;
reading the information data out of each of destination blocks of the plurality of blocks every time the information data is written to the destination block, and detecting a number of error bits in the read-out information data for each destination block; and
writing the information data to a block differing from the destination block if the number of error bits exceeds a prescribed threshold.

10. The data writing method according to claim 9, further comprising restoring data, when the number of error bits exceeds an upper limit of a number of error bits that can be corrected, by writing back-up data to a block where the number of error bits exceeds the upper limit.
